(19) United States
(12) Patent Application Publication
(10) Pub. No.: US 2026/0159942 A1
(43) Pub. Date: Jun. 11, 2026

(54) FILM FORMATION METHOD AND FILM FORMATION APPARATUS

(71) Applicant: Tokyo Electron Limited, Tokyo (JP)

(72) Inventors: Yumiko KAWANO, Nirasaki City (JP); Shuji AZUMO, Nirasaki City (JP)

(21) Appl. No.: 19/181,610

(22) Filed: Apr. 17, 2025

Related U.S. Application Data
(63) Continuation of application No. PCT/JP2023/037422, filed on Oct. 16, 2023.

(30) Foreign Application Priority Data
Oct. 28, 2022 (JP) 2022-173130
Sep. 25, 2023 (JP) 2023-160180

(51) Int. Cl. C23C 16/02; C23C 16/04; C23C 16/455; C23C 16/52

(52) U.S. Cl. CPC C23C 16/0245; C23C 16/04; C23C 16/45544; C23C 16/52

(57) ABSTRACT

A film formation method includes: preparing a substrate having a first film and a second film made of a material different from a material of the first film in different regions of a surface of the substrate; supplying, to the surface of the substrate, a first cleaning gas that removes a contaminant on the surface of the substrate; supplying, to the surface of the substrate, a second cleaning gas plasmarized to remove a residue of the first cleaning gas adhering to the surface of the substrate; and after supplying the second cleaning gas, selectively forming a self-assembled monolayer on a surface of the second film relative to a surface of the first film. The first cleaning gas includes at least one selected from a group consisting of a carboxylic acid compound, a phosphonic acid compound, a nitro compound, and a thiol compound.

### CROSS-REFERENCE TO RELATED APPLICATIONS

This application is a bypass continuation application of International Application No. PCT/JP2023/037422 having an international filing date of Oct. 16, 2023 and designating the United States, the international application being based upon and claiming the benefit of priority from Japanese Patent Application Nos. 2022-173130 and 2023-160180, filed on Oct. 28, 2022, and Sep. 25, 2023, respectively, the entire contents of which are incorporated herein by references.

### TECHNICAL FIELD

The present disclosure relates to a film formation method and a film formation apparatus.

### BACKGROUND

Patent Document 1 discloses a film formation method of forming a target film on one portion of a surface of a substrate while inhibiting the formation of the target film on another portion of the surface of the substrate using a self-assembled monolayer (SAM). The film formation method disclosed in Patent Document 1 includes reducing a natural oxide film formed on a surface of a first material layer, before forming a SAM on the surface of the first material layer, and oxidizing the surface of the first material layer.

### PRIOR ART DOCUMENT

### Patent Document

Patent Document 1: Japanese Laid-Open Patent Publication No. 2021-057563

### SUMMARY

According to one embodiment of the present disclosure, a film formation method includes: preparing a substrate having a first film and a second film made of a material different from a material of the first film in different regions of a surface of the substrate; supplying, to the surface of the substrate, a first cleaning gas that removes a contaminant on the surface of the substrate; supplying, to the surface of the substrate, a second cleaning gas plasmarized to remove a residue of the first cleaning gas adhering to the surface of the substrate; and after supplying the second cleaning gas, selectively forming a self-assembled monolayer on a surface of the second film relative to a surface of the first film. The first cleaning gas includes at least one selected from a group consisting of a carboxylic acid compound, a phosphonic acid compound, a nitro compound, and a thiol compound.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a film formation method according to an embodiment.

FIG. 2 is a flowchart illustrating an example of a subroutine of S107.

FIG. 3 is a flowchart illustrating an example of a subroutine of S108.

FIG. 4A is a cross-sectional view illustrating an example of S101.

FIG. 4B is a cross-sectional view illustrating an example of S102.

FIG. 4C is a cross-sectional view illustrating an example of S103.

FIG. 4D is a cross-sectional view illustrating an example of S104.

FIG. 5A is a cross-sectional view illustrating an example of S105.

FIG. 5B is a cross-sectional view illustrating an example of S106.

FIG. 5C is a cross-sectional view illustrating an example of S107.

FIG. 5D is a cross-sectional view illustrating an example of S108.

FIG. 6A is a cross-sectional view illustrating a first modification of S101.

FIG. 6B is a cross-sectional view illustrating a second modification of S101.

FIG. 6C is a cross-sectional view illustrating a third modification of S101.

FIG. 7 is a plan view illustrating a film formation apparatus according to an embodiment.

FIG. 8 is a cross-sectional view illustrating an example of a first processor in FIG. 7.

FIG. 9 is a flowchart illustrating a modification of FIG. 1.

FIG. 10 is a cross-sectional view illustrating an example of progress of S102, S103, S103A, and S104 in FIG. 9.

### DETAILED DESCRIPTION

Hereinafter, embodiments of the present disclosure will be described with reference to the accompanying drawings. In each drawing, the same or corresponding components will be denoted by the same reference numerals, and descriptions thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

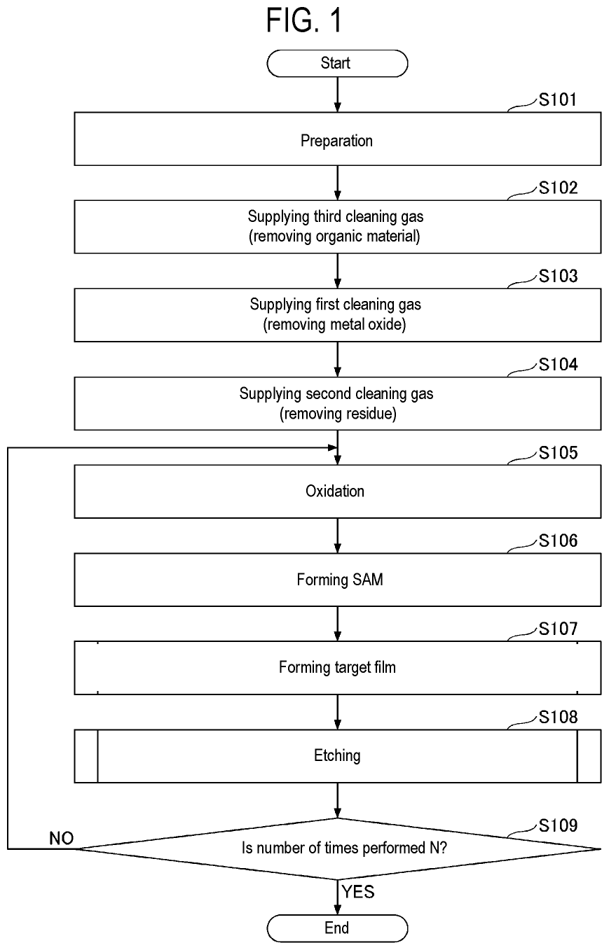

A film formation method according to an embodiment will now be described with reference mainly to FIGS. 1 to 3, 4A to 4D, and 5A to 5D. The film formation method includes, for example, Operations S101 to S109 illustrated in FIG. 1. The film formation method may include at least Operations S101, S103, S104, and S106 and may not include, for example, Operations S102, S105, and S107 to S109. The film formation method may include Operations other than Operations S101 to S109 illustrated in FIG. 1.

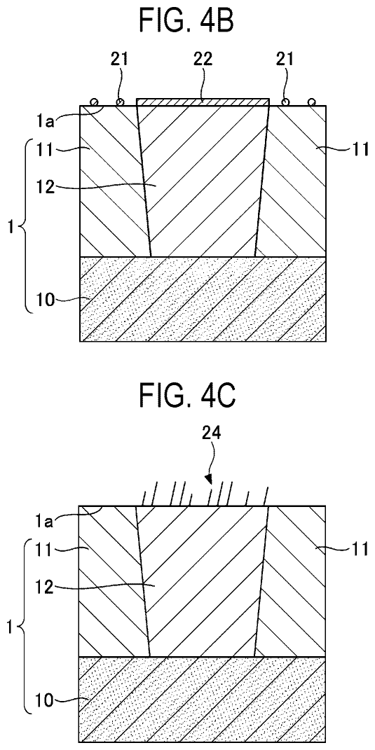

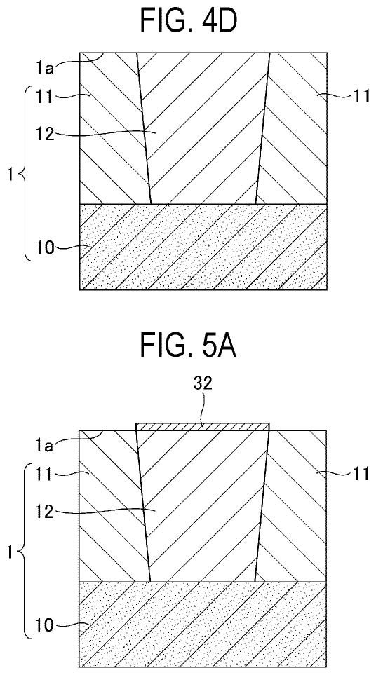

Operation S101 includes preparing a substrate 1 as illustrated in FIG. 4A. The substrate 1 includes a base substrate 10. The base substrate 10 is, for example, a silicon wafer, a compound semiconductor wafer, or a glass substrate. The substrate 1 includes an insulating film 11 and a conductive film 12 in different regions of a substrate surface 1a. The substrate surface 1a is, for example, an upper surface of the substrate 1. The insulating film 11 and the conductive film 12 are formed on the base substrate 10. Another functional film may be formed between the base substrate 10 and the insulating film 11 or between the base substrate 10 and the conductive film 12. The insulating film 11 is an example of a first film, and the conductive film 12 is an example of a second film. Materials of the first film and the second film are not particularly limited.

The insulating film 11 is, for example, an interlayer insulating film. The interlayer insulating film is desirably a low dielectric constant (low-k) film. The insulating film 11 is, without being particularly limited to, for example, a SiO film, a SiN film, a SiOC film, a SiON film, or a SiOCN film. Here, the SiO film means a film including silicon (Si) and oxygen (O). An atomic ratio of Si to O in the SiO film is usually 1:2. However, in the present application, the atomic ratio of Si to O in the SiO film is not limited to 1:2. Similarly, each of the SiN film, the SiOC film, the SiON film, and the SiOCN film means a film including corresponding elements and is not limited to a stoichiometric ratio. The insulating film 11 has a recess formed in the substrate surface 1a. The recess is a trench, a contact hole, or a via hole.

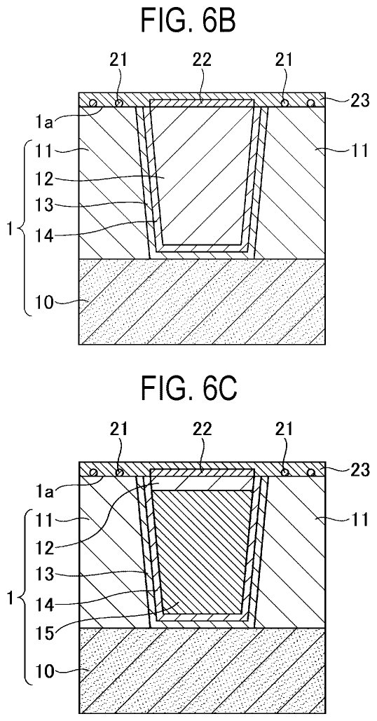

The conductive film 12 may fill the recess of the insulating film 11. The conductive film 12 is, for example, a metal film. The metal film is, for example, a Cu film, a Co film, a Ru film, a W film, or a Mo film. The conductive film 12 may be a cap film. In other words, as illustrated in FIG. 6C, a second conductive film 15 may be embedded in the recess of the insulating film 11. The second conductive film 15 may be covered by the conductive film 12. The second conductive film 15 is made of a metal different from that of the conductive film 12. For example, the second conductive film 15 is the Cu film, and the conductive film 12 (cap film) is the Co film or the Ru film.

The substrate 1 may further include a third film formed on the substrate surface 1a. The third film is, for example, a barrier film 13 (see FIG. 6A, 6B, or 6C). The barrier film 13 is formed between the insulating film 11 and the conductive film 12 to suppress metal from diffusing from the conductive film 12 to the insulating film 11. The barrier film 13 is, without being limited to, for example, a TaN layer or a TiN layer. Here, the TiN film means a film including titanium (Ti) and nitrogen (N). An atomic ratio of Ti to N in the TiN film is usually 1:1 but is not limited thereto. Similarly, the TaN film means a film including corresponding elements and is not limited to a stoichiometric ratio.

The substrate 1 may further include a fourth film formed on the substrate surface 1a. The fourth film is, for example, a liner film 14 (see FIGS. 6B and 6C). The liner film 14 is formed between the conductive film 12 and the barrier film 13. The liner film 14 is formed on the barrier film 13 to assist the formation of the conductive film 12. The conductive film 12 is formed on the liner film 14. For example, the conductive film 12 is the Cu film, and the liner film 14 is the Co film or the Ru film.

As illustrated in FIG. 4A, a contaminant 21 may be present on the surface of the insulating film 11. The contaminant 21 is, for example, a metal adhering to the insulating film 11 during the formation of the conductive film 12 or a metal oxide formed by reaction between the metal and the atmosphere. In addition, a contaminant 22 may be present on the surface of the conductive film 12. The contaminant 22 is, for example, a metal oxide formed by reaction between the conductive film 12 and the atmosphere and is a so-called natural oxide film. Further, a contaminant 23 may be present on the substrate surface 1a. The contaminant 23 is an organic material. The organic material is, for example, a deposit including carbon and adheres to the substrate 1 during a processing process. The organic material may be layered.

Operation S102 includes supplying a third cleaning gas to the substrate surface 1a. The third cleaning gas removes the contaminant 23 (for example, the layered organic material) as illustrated in FIG. 4B. By removing the contaminant 23, the other contaminants 21 and 22 may be exposed. In a case in which there is no layered organic material on the substrate surface 1a or in a case in which the layered organic material is present on the substrate surface 1a but is thin, supplying the third cleaning gas (Operation S102) may be omitted. The third cleaning gas may remove the metal or the metal oxide in addition to the organic material. However, the efficiency of removing the metal or the metal oxide by the third cleaning gas is lower than that by a first cleaning gas described later.

The third cleaning gas includes at least a reducing gas such as a H₂ gas, and may include a nitrogen-containing gas such as a N₂ gas in addition to the reducing gas. The reducing gas may be supplied to the substrate surface 1a in a plasmarized state. The plasmarized reducing gas and an oxygen-containing gas may be supplied to the substrate surface 1a in this order. The oxygen-containing gas includes at least one selected from a group consisting of an O₂ gas, an O₃ gas, a H₂O gas, a NO gas, a NO₂ gas, and a N₂O gas.

An example of processing conditions used in Operation S102 is as follows.
Flow rate of H₂ gas: 50 sccm to 5,000 sccm
Flow rate of N₂ gas: 50 sccm to 10,000 sccm
Flow rate of Ar gas: 20 sccm to 10,000 sccm
Ratio of H₂ gas in third cleaning gas: 10 vol % to 60 vol %
Ratio of N₂ gas in third cleaning gas: 10 vol % to 80 vol %
Power supply frequency for plasma generation: 10 MHz to 40 MHz
Power for plasma generation: 100 W to 400 W
Processing time: 5 seconds to 120 seconds
Processing temperature (substrate temperature): 80 degrees C. to 350 degrees C.
Processing pressure: 50 Pa to 2,000 Pa.

Operation S103 includes supplying the first cleaning gas to the substrate surface 1a. As illustrated in FIG. 4C, the first cleaning gas removes the contaminants 21 and 22 (for example, the metal or metal oxide). The removal of the contaminants 21 and 22 is a dry process. Unlike a wet process, the dry process is more likely to prevent oxidation of the substrate 1. In the wet process, a processing liquid (for example, an aqueous citric acid solution) is supplied to the substrate 1 in an atmospheric atmosphere, so that the substrate 1 is more likely to be oxidized during processing. Unlike the wet process, the dry process may perform pre-processing or post-processing without breaking a vacuum atmosphere. The first cleaning gas may also remove the organic material in addition to the metal or metal oxide. However, the efficiency of removing the organic material by the first cleaning gas is lower than that by the third cleaning gas.

The first cleaning gas includes at least one selected from a group consisting of, for example, a carboxylic acid compound, a phosphonic acid compound, a nitro compound, and a thiol compound. The carboxylic acid compound is expressed by a general formula “R—COOH”. The phosphonic acid compound is expressed by a general formula “R—P(═O)(OH)₂”. The nitro compound is expressed by a general formula “R—NO₂”. The thiol compound is expressed by a general formula “R—SH”.

In these general formulas, R is, for example, a hydrocarbon group, or a hydrocarbon group in which at least a portion of hydrogen is replaced with fluorine. Specifically, for example, R is “CF₃—(CF₂)_{X}—”, “CF₃—(CF₂)_{X}—CH₂—CH₂—”, or “CH₃—(CH₂)_{X}—”. X is an integer in a range of 1 to 17. Specific examples of the carboxylic acid compound may include PFBA (CF₃(CF₂)₂COOH), formic acid (HCOOH), acetic acid (CH₃COOH), propionic acid (CH₃CH₂COOH), and octanoic acid (CH₃(CH₂)₆COOH). A specific example of the nitro compound may include PFNO (CF₃(CF₂)₅CH₂CH₂NO₂).

An example of processing conditions used in Operation S103 is as follows.
Flow rate of PFBA gas: 10 sccm to 100 sccm
Processing time: 30 seconds to 10 minutes
Processing temperature (substrate temperature): 80 degrees C. to 350 degrees C.
Processing pressure: 100 Pa to 300 Pa.

Operation S104 includes supplying a plasmarized second cleaning gas to the substrate surface 1a. The plasmarized second cleaning gas removes a residue 24 (see FIG. 4C) of the first cleaning gas as illustrated in FIG. 4D. The residue 24 remains mainly on the surface of the conductive film 12. The residue 24 is an organic material. The second cleaning gas includes at least a reducing gas such as a H₂ gas, and may include a nitrogen-containing gas such as a N₂ gas in addition to the reducing gas. Processing conditions used in Operation S104 are the same as those used in Operation S102, and therefore descriptions thereof will be omitted.

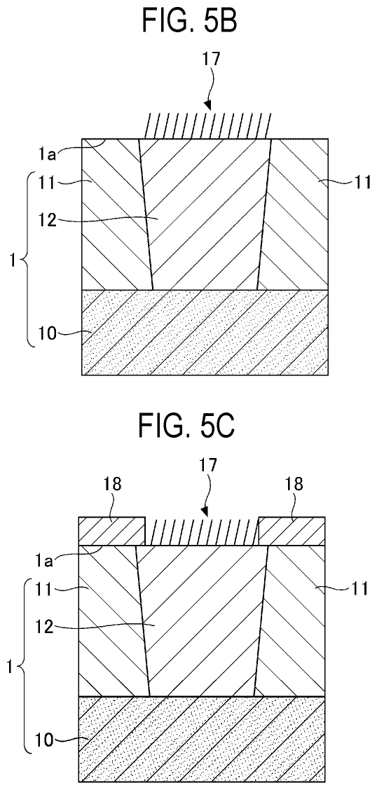

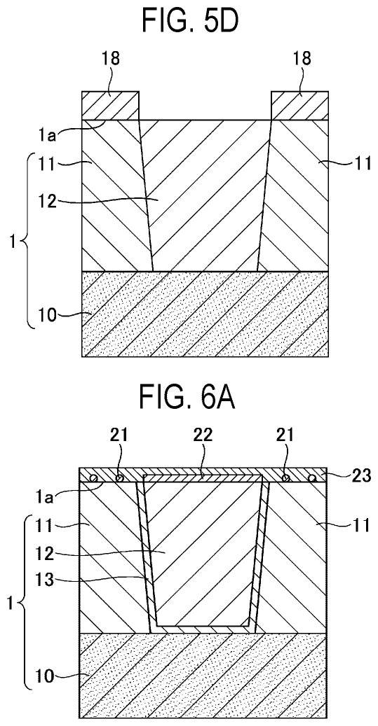

Operation S105 includes supplying an oxygen-containing gas to the substrate surface 1a. The oxygen-containing gas includes at least one selected from a group consisting of an O₂ gas, an O₃ gas, a H₂O gas, a NO gas, a NO₂ gas, and a N₂O gas. An oxide film 32 having a desired film thickness and desired film quality is obtained in Operation S105 (see FIG. 5A). Unlike the natural oxide film, the film thickness and film quality of the oxide film 32 may be controlled by a raw material gas and film formation conditions. By forming the oxide film 32 having the desired film thickness and desired film quality, a dense self-assembled monolayer (SAM) may be formed on the surface of the conductive film 12 in Operation S106 described later.

An example of processing conditions used in Operation S105 is as follows.
Flow rate of O₂ gas: 50 sccm to 4,000 sccm
Processing time: 1 second to 300 seconds
Processing temperature: 80 degrees C. to 350 degrees C.
Processing pressure: 50 Pa to 2,000 Pa.

Operation S106 includes selectively forming a self-assembled monolayer 17 on the surface of the conductive film 12 relative to the surface of the insulating film 11 (see FIG. 5B). Hereinafter, the self-assembled monolayer 17 may be referred to as an SAM 17. The SAM 17 is formed by supplying an organic compound gas to the substrate surface 1a. The organic compound gas is a raw material gas of the SAM 17.

The raw material gas of the SAM 17 is not particularly limited but may include a thiol compound. Specific examples of the thiol compound may include CF₃(CF₂)₅CH₂CH₂SH (1H, 1H, 2H, 2H-perfluorooctanethiol: PFOT) and CH₃(CH₂)₅SH (hexanethiol: HT). The thiol compound is more likely to be chemically adsorbed onto the surface of the conductive film 12 than on the surface of the insulating film 11. Therefore, the SAM 17 is selectively formed on the surface of the conductive film 12 relative to the surface of the insulating film 11. The SAM 17 is hardly formed on the surface of the insulating film 11.

When the oxide film 32 is formed (in Operation S105) before the formation of the SAM 17 (in Operation S106), a density of the SAM 17 may be improved compared to the case in which the formation of the oxide film 32 (in Operation S105) is not performed. Thus, a blocking performance of the SAM 17 may be improved in the formation of a second insulating film 18 (in Operation S107) described later. Since the thiol compound is chemically adsorbed onto the oxide film 32 while reducing the oxide film 32, the oxide film 32 may not remain after Operation S106.

Operation S106 may include alternately supplying a thiol compound gas and an oxygen-containing gas to the substrate surface 1a. The oxide film 32 may be formed during the formation of the SAM 17. The formation of the oxide film 32 may be performed in a dispersed manner, which makes it possible to suppress surface roughness due to the formation of the oxide film 32.

The raw material gas of the SAM 17 is not limited to the thiol compound. The raw material gas of the SAM 17 may include a phosphonic acid compound, a carboxylic acid compound, or a nitro compound. The first cleaning gas and the raw material gas of the SAM 17 may include the same organic compound or different organic compounds but desirably include the same organic compound. By using the same organic compound, the number of chambers used may be reduced, which results in cost reduction.

Table 1 below shows suitable combinations of the conductive film 12, the first cleaning gas, and the raw material gas of the SAM 17. These combinations are not limited to the combinations illustrated in Table 1.

TABLE 1

| Conductive Film | First Cleaning Gas | Raw material gas of SAM |
|---|---|---|
| Cu | R—COOH, R—P(═O)(OH)₂ | R—SH, R—P(═O)(OH)₂ |
| Co | R—NO₂, R—P(═O)(OH)₂ | R—NO₂, R—P(═O)(OH)₂ |
| Ru, W, Mo | R—COOH, R—P(═O)(OH)₂ | R—COOH, R—P(═O)(OH)₂ |

The raw material gas of the SAM 17 may include an olefin compound or an organic silane compound. The olefin compound is expressed by a general formula “R—CH═CH₂”. The organic silane compound is, for example, a trichlorosilane compound, a methoxysilane compound, or an ethoxysilane compound. The trichlorosilane organic compound is expressed by a general formula “R—SiCl₃”. The methoxysilane organic compound is expressed by a general formula “R—Si(OCH₃)₃”. The ethoxysilane organic compound is expressed by a general formula “R—Si(OCH₂CH₃)₃”.

An example of processing conditions used in Operation S106 is as follows.
Flow rate of PFOT gas: 50 sccm to 200 sccm
Processing time: 3 seconds to 120 seconds
Processing temperature: 80 degrees C. to 350 degrees C.
Processing pressure: 50 Pa to 4,000 Pa.

According to the present embodiment, the surface of the insulating film 11 is cleaned before the formation of the SAM 17. Specifically, the contaminant 21 (for example, the metal or metal oxide) adhering to the surface of the insulating film 11 is removed by the first cleaning gas. This makes it possible to suppress the formation of the SAM 17 on the surface of the insulating film 11.

Further, according to the present embodiment, the surface of the conductive film 12 is cleaned before the formation of the SAM 17. Specifically, the contaminant 22 (for example, the natural oxide film) adhering to the surface of the conductive film 12 is removed by the first cleaning gas, and then the residue 24 of the first cleaning gas is removed by the second cleaning gas. This makes it possible to uniformly and densely form the SAM 17 on the surface of the conductive film 12.

When the raw material gas of the SAM 17 includes the nitro compound, the second cleaning gas desirably includes a nitrogen-containing gas in addition to a reducing gas. By slightly nitriding the surface of the conductive film 12 using the nitrogen-containing gas, the nitro compound is easily adsorbed onto the surface of the conductive film 12. Therefore, the density of the SAM 17 may be improved.

As described above, according to the present embodiment, the formation of the SAM 17 on the surface of the insulating film 11 may be suppressed, and the uniform and dense SAM 17 may be formed on the surface of the conductive film 12. That is, the SAM 17 may be selectively formed in a desired region (for example, the surface of the conductive film 12). As a result, the second insulating film 18 may be selectively formed in Operation S107 described below.

Operation S107 includes forming the second insulating film 18 on the surface of the insulating film 11 while inhibiting the formation of the second insulating film 18 on the surface of the conductive film 12 using the SAM 17 (see FIG. 5C). The second insulating film 18 is an example of a target film. The second insulating film 18 is formed by a chemical vapor deposition (CVD) method or an atomic layer deposition (ALD) method.

According to the present embodiment, as described above, the formation of the SAM 17 on the surface of the insulating film 11 may be suppressed. Thus, the second insulating film 18 may be efficiently formed on the surface of the insulating film 11. Specifically, the film thickness of the second insulating film 18 per cycle may be improved. Further, according to the present embodiment, since the contaminant 21 (for example, the metal) does not remain between the insulating film 11 and the second insulating film 18, the occurrence of leakage current may be suppressed. In addition, according to the present embodiment, since the contaminant 22 (for example, the natural oxide film) does not remain on the surface of the conductive film 12, wiring resistance may be reduced.

The second insulating film 18 is, without being particularly limited to, for example, an AlO film, a SiO film, a SiN film, a ZrO film, or a HfO film. Here, the AlO film means a film including aluminum (Al) and oxygen (O). An atomic ratio of Al to O in an AlO film is usually 2:3. However, in the present application, the atomic ratio of Al to O in the AlO film is not limited to 2:3. Similarly, each of the SiO film, the SiN film, the ZrO film, and the HfO film means a film including corresponding elements and is not limited to a stoichiometric ratio.

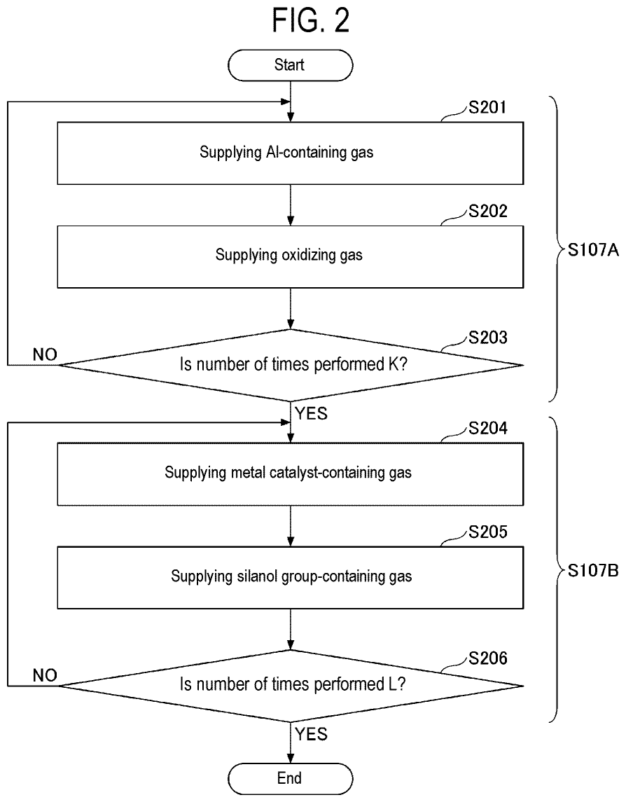

As illustrated in FIG. 2, a method of forming the second insulating film 18 may include forming the AlO film (in Operation S107A) and forming the SiO film (in Operation S107B). By forming the AlO film in advance, the formation of the SiO film using a dehydration condensation reaction of a silanol group may be promoted. Forming the AlO film before the formation of the SiO film is particularly effective when the insulating film 11 is a low-k film.

Operation S107A includes alternately supplying an Al-containing gas (in Operation S201) and an oxidizing gas (in Operation S202) K times (where K is an integer equal to or greater than 1). A specific example of the Al-containing gas is a trimethylaluminum (TMA) gas. A specific example of the oxidizing gas is water vapor (H₂O gas).

K may be an integer of 2 or more, and Operations S201 and S202 described above may be performed repeatedly. When the number of times performed is less than K (NO in Operation S203), the thickness of the AlO film is less than a target value. Thus, Operations S201 and S202 described above are performed again. On the other hand, when the number of times performed is K (YES in Operation S203), the thickness of the AlO film has reached the target value. Thus, Operation S107A ends.

An example of processing conditions used in Operation S107A is as follows.
Operation S201
Flow rate of TMA gas: 10 sccm to 100 sccm
Processing time: 0.05 seconds to 10 seconds
Processing temperature: 80 degrees C. to 350 degrees C.
Processing pressure: 133 Pa to 1,200 Pa
Operation S202
Flow rate of H₂O gas: 50 sccm to 500 sccm
Processing time: 0.1 seconds to 10 seconds
Processing temperature: 80 degrees C. to 350 degrees C.
Processing pressure: 133 Pa to 1,200 Pa
Operation S203
Set number of times (K times): 2 times to 20 times.

Operation S107B includes alternately supplying a metal catalyst-containing gas (in Operation S204) and a silanol group-containing gas (in Operation S205) L times (where L is an integer of 1 or more). The metal catalyst-containing gas contains a metal catalyst (for example, Al) that promotes a dehydration condensation reaction of a silanol group included in the silanol group-containing gas. A specific example of the metal catalyst-containing gas is a trimethylaluminum (TMA) gas. A SiO film is formed by the dehydration condensation reaction of the silanol group. A specific example of the silanol group-containing gas is tris(tert-pentoxy)silanol (TPSOL).

L may be an integer of 2 or more, and Operations S204 and S205 described above may be repeatedly performed. When the number of times performed is less than L (NO in Operation S206), the thickness of the SiO film is less than a target value. Thus, Operations S204 and S205 are performed again. On the other hand, when the number of times performed is L (YES in Operation S206), the thickness of the SiO film has reached the target value. Thus, Operation S107B ends.

An example of processing conditions used in Operation S107B is as follows. The TPSOL gas is supplied by vaporizing a TPSOL liquid.
Operation S204
Flow rate of TMA gas: 10 sccm to 100 sccm
Processing time: 0.05 seconds to 100 seconds
Processing temperature: 80 degrees C. to 350 degrees C.
Processing pressure: 133 Pa to 1,200 Pa
Operation S205
Flow rate of TPSOL gas: 0.1 g/min to 0.5 g/min
Processing time: 3 seconds to 120 seconds
Processing temperature: 80 degrees C. to 350 degrees C.
Processing pressure: 133 Pa to 1,200 Pa
Operation S203
Set number of times (K times): 1 time to 5 times.

However, as illustrated in FIG. 5C, the SAM 17 inhibits the formation of the second insulating film 18, but the blocking ability of the SAM 17 is not perfect and the second insulating film 18 protrudes laterally from the surface of the insulating film 11.

Operation S108 includes etching an unnecessary portion of the second insulating film 18 (see FIG. 5D). Since an opening width of the second insulating film 18 may be enlarged, the wiring resistance of the substrate 1 may be reduced. When the organic compound, which is the raw material of the SAM 17, includes fluorine, Operation S108 includes supplying an H₂O-containing gas to the substrate surface 1a. Hydrofluoric acid is generated by reaction between the H₂O-containing gas and the SAM 17. The unnecessary portion of the second insulating film 18 may be etched by the generated hydrofluoric acid. A product generated by etching is volatile and is vaporized and exhausted. As described above, the second insulating film 18 is, for example, an AlO film, a SiO film, a SiN film, a ZrO film, or a HfO film. All of these films may be etched with the hydrofluoric acid.

As described above, the hydrofluoric acid is generated by the reaction between the H₂O-containing gas and the SAM 17. Therefore, the hydrofluoric acid is generated only in the vicinity of the SAM 17. Thus, while the unnecessary portion of the second insulating film 18 is etched, a necessary portion of the second insulating film 18 (a portion deposited on the surface of the insulating film 11) is not etched. The unnecessary portion of the second insulating film 18 may be selectively removed.

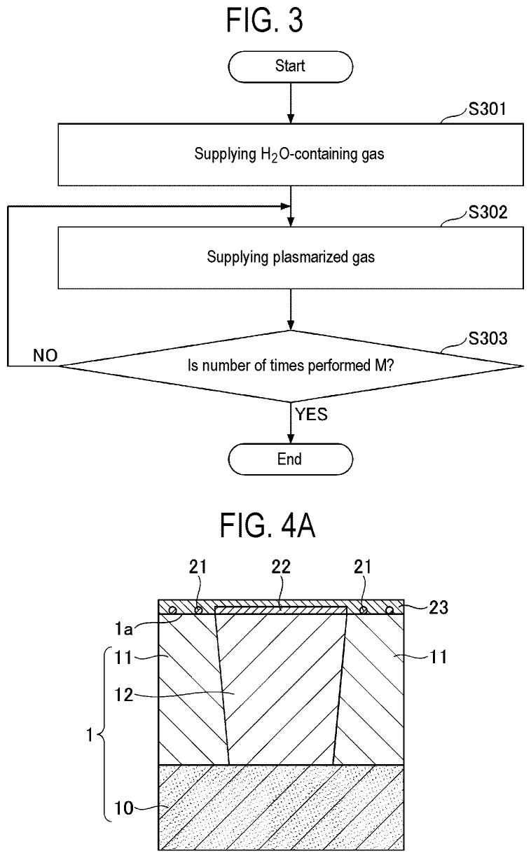

Operation S108 includes, for example, Operations S301 to S303 illustrated in FIG. 3. Operation S301 includes supplying the H₂O-containing gas to the substrate surface 1a. The H₂O-containing gas may include only the H₂O gas or include both the H₂O gas and a carrier gas.

Operation S302 includes supplying a plasmarized gas to the substrate surface 1a. The plasmarized gas is obtained by plasmarizing at least one selected from a group consisting of, for example, a H₂ gas, an Ar gas, a N₂ gas, and a NH₃ gas. The SAM 17 may be decomposed and the generation of the hydrofluoric acid may be promoted by the supply of the plasmarized gas.

The plasmarized gas is desirably obtained by plasmarizing a reducing gas or an inert gas so that the conductive film 12 exposed after the SAM 17 is decomposed is not oxidized. In particular, when a plasmarized H₂ gas is used, the second insulating film 18 may be modified and thus the generation of the leakage current may be suppressed.

Operation S303 includes checking whether or not Operations S301 and S302 have been performed M times (where M is an integer equal to or greater than 1). M may be an integer equal to or greater than 2. When the number of times performed is less than M times (NO in Operation S303), Operations S301 and S302 are performed again. On the other hand, when the number of times performed reaches M times (YES in Operation S303), the present processing ends.

In FIG. 3, while the H₂O-containing gas and the plasmarized gas are illustrated as being sequentially supplied without being simultaneously supplied, the H2O-containing gas and the plasmarized gas may be simultaneously supplied. In either case, the SAM 17 may be decomposed by the supply of the plasmarized gas and the generation of the hydrofluoric acid may be promoted. However, when the H₂O-containing gas and the plasmarized gas are sequentially supplied, the H₂O-containing gas may be prevented from being plasmarized, and the generation of oxygen plasma may be prevented, thereby preventing the oxidation of the substrate surface 1a.

The set number of times (M times) in Operation S303 may be once but is desirably multiple times. By performing the supply of the plasmarized gas multiple times, the decomposition of the SAM 17 may be gradually performed, and the hydrofluoric acid may be generated over a long period of time. As a result, the opening width of the second insulating film 18 may be expanded, and thus the wiring resistance of the substrate 1 may be reduced.

An example of processing conditions used in Operation S108 is as follows.
Operation S301
Flow rate of H₂O gas: 10 sccm to 500 sccm
Processing time: 0.1 sec to 120 sec
Processing temperature: 80 degrees C. to 350 degrees C.
Processing pressure: 50 Pa to 1,200 Pa
Operation S302
Flow rate of H₂ gas: 200 sccm to 3,000 sccm
Flow rate of Ar gas: 100 sccm to 6,000 sccm
Ratio of H₂ gas in mixed gas of H₂ gas and Ar gas: 20 vol % to 90 vol %
Power supply frequency for plasma generation: 10 MHz to 60 MHz
Power for plasma generation: 50 W to 600 W
Processing time: 2 sec to 120 sec
Processing temperature: 80 degrees C. to 350 degrees C.
Processing pressure: 50 Pa to 1,200 Pa
Operation S303
Set number of times (M times): 1 time to 50 times.

Operation S109 includes checking whether or not Operations S105 to S108 have been performed N times (where N is an integer equal to or greater than 1). N may be an integer equal to or greater than 2. When the number of times performed is less than N (NO in Operation S109), Operations S105 to S108 are performed again. On the other hand, when the number of times has reached N times (YES in Operation S109), the present processing ends.

In the case in which the set number of times (N times) of Operation S109 is multiple times, a first round of Operation S107 includes Operations S107A and S107B in this order, whereas a second round and subsequent rounds of Operation S107 desirably does not include Operation S107A and includes Operation S107B alone. In the second round and subsequent rounds of Operation S107, a SiO film may be efficiently formed even without forming an AlO film in advance. Further, by not forming the AlO film in advance, an increase in a dielectric constant may be suppressed.

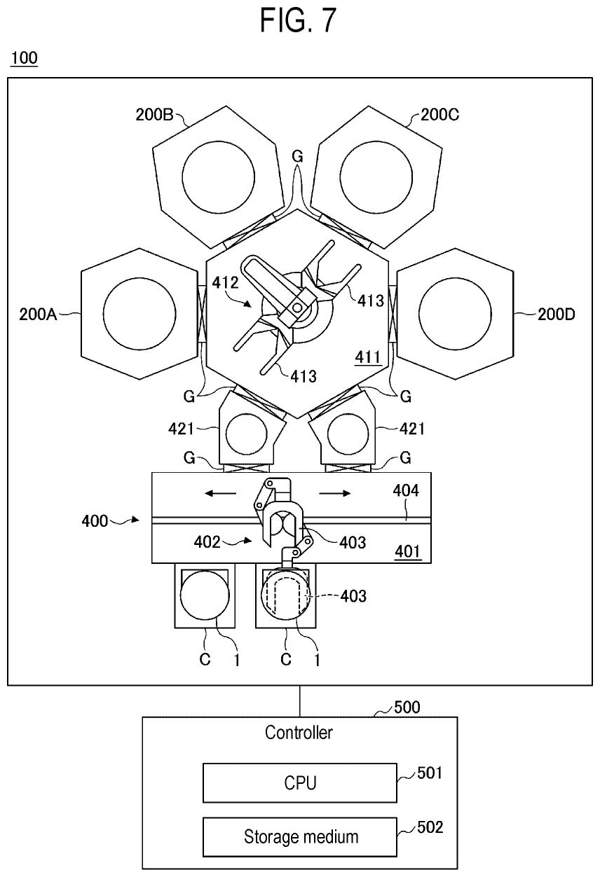

Next, a film formation apparatus 100 for carrying out the above-described film formation method will be described with reference to FIG. 7. As illustrated in FIG. 7, the film formation apparatus 100 includes a first processor 200A, a second processor 200B, a third processor 200C, a fourth processor 200D, a transferrer 400, and a controller 500. The first processor 200A performs Operations S102 and S103 in FIG. 1. The second processor 200B performs Operations S104 and S105 in FIG. 1. The third processor 200C performs S106 in FIG. 1. The fourth processor 200D performs Operations S107 and S108 in FIG. 1. The first processor 200A, the second processor 200B, the third processor 200C, and the fourth processor 200D may identical to or different from each other in structure. All of Operations S102 to S108 may be performed only by the first processor 200A. The transferrer 400 transfers the substrate 1 to the first processor 200A, the second processor 200B, the third processor 200C, and the fourth processor 200D. The controller 500 controls the first processor 200A, the second processor 200B, the third processor 200C, the fourth processor 200D, and the transferrer 400.

The transferrer 400 includes a first transfer chamber 401 and a first transfer mechanism 402. An internal atmosphere of the first transfer chamber 401 is an atmospheric atmosphere. The first transfer mechanism 402 is provided inside the first transfer chamber 401. The first transfer mechanism 402 includes an arm 403 that holds the substrate 1 and travels along a rail 404. The rail 404 extends in an arrangement direction of carriers C.

The transferrer 400 further includes a second transfer chamber 411 and a second transfer mechanism 412. An internal atmosphere of the second transfer chamber 411 is a vacuum atmosphere. The second transfer mechanism 412 is provided inside the second transfer chamber 411. The second transfer mechanism 412 includes an arm 413 that holds the substrate 1. The arm 413 is arranged to be movable in a vertical direction and a horizontal direction and to be rotatable around a vertical axis. The first processor 200A, the second processor 200B, the third processor 200C, and the fourth processor 200D are connected to the second transfer chamber 411 via different gate valves G.

Further, the transferrer 400 includes load lock chambers 421 between the first transfer chamber 401 and the second transfer chamber 411. An internal atmosphere of each load lock chamber 421 is switched between a vacuum atmosphere and an atmospheric atmosphere by a pressure regulating mechanism (not illustrated). Thus, an interior of the second transfer chamber 411 may always be maintained in the vacuum atmosphere. In addition, gas may be suppressed from flowing from the first transfer chamber 401 into the second transfer chamber 411. Gate valves G are provided between the first transfer chamber 401 and the load lock chambers 421, and between the second transfer chamber 411 and the load lock chambers 421.

The controller 500 is, for example, a computer, and includes a central processing unit (CPU) 501 and a storage medium 502 such as a memory. The storage medium 502 stores programs for controlling various processes executed by the film formation apparatus 100. The controller 500 controls the operation of the film formation apparatus 100 by causing the CPU 501 to execute the programs stored in the storage medium 502. The controller 500 controls the first processor 200A, the second processor 200B, the third processor 200C, the fourth processor 200D, and the transferrer 400 so as to execute the above-described film formation method.

Next, the operation of the film formation apparatus 100 will be described. First, the first transfer mechanism 402 takes the substrate 1 out of the carrier C, transfers the same to the load lock chamber 421, and is withdrawn from the load lock chamber 421. Thereafter, the internal atmosphere of the load lock chamber 421 is switched from the atmospheric atmosphere to the vacuum atmosphere. Thereafter, the second transfer mechanism 412 takes the substrate 1 out of the load lock chamber 421 and transfers the same to the first processor 200A.

Subsequently, the first processor 200A performs Operations S102 and S103. Thereafter, the second transfer mechanism 412 takes the substrate 1 out of the first processor 200A and transfers the same to the second processor 200B. During this time, since an ambient atmosphere of the substrate 1 may be maintained in the vacuum atmosphere, unintended oxidation of the substrate 1 may be suppressed.

Then, the second processor 200B performs Operations S104 and S105. Thereafter, the second transfer mechanism 412 takes the substrate 1 out of the second processor 200B and transfers the same to the third processor 200C. During this time, since the ambient atmosphere of the substrate 1 may be maintained in the vacuum atmosphere, unintended oxidation of the substrate 1 may be suppressed.

Subsequently, the third processor 200C performs Operation S106. Thereafter, the second transfer mechanism 412 takes the substrate 1 out of the third processor 200C and transfers the same to the fourth processor 200D. During this time, since the ambient atmosphere of the substrate 1 may be maintained in the vacuum atmosphere, the deterioration of the blocking performance of the SAM 17 may be suppressed.

Subsequently, the fourth processor 200D performs Operations S107 and S108. Thereafter, the controller 500 checks whether or not Operations S105 and S108 have been performed a set number of times (N times). When the number of times performed has not reached the set number, the second transfer mechanism 412 takes the substrate 1 out of the fourth processor 200D and transfers the same to the second processor 200B. Subsequently, the controller 500 controls the second processor 200B, the third processor 200C, the fourth processor 200D, and the transferrer 400 so as to execute Operations S105 to S108.

On the other hand, when the number of times performed has reached the set number, the second transfer mechanism 412 takes the substrate 1 out of the fourth processor 200D, transfers the same to the load lock chamber 421, and is withdrawn from the load lock chamber 421. Thereafter, the internal atmosphere of the load lock chamber 421 is switched from the vacuum atmosphere to the atmospheric atmosphere. Thereafter, the first transfer mechanism 402 takes the substrate 1 out of the load lock chamber 421 and accommodates the same in the carrier C. Then, the processing of the substrate 1 ends.

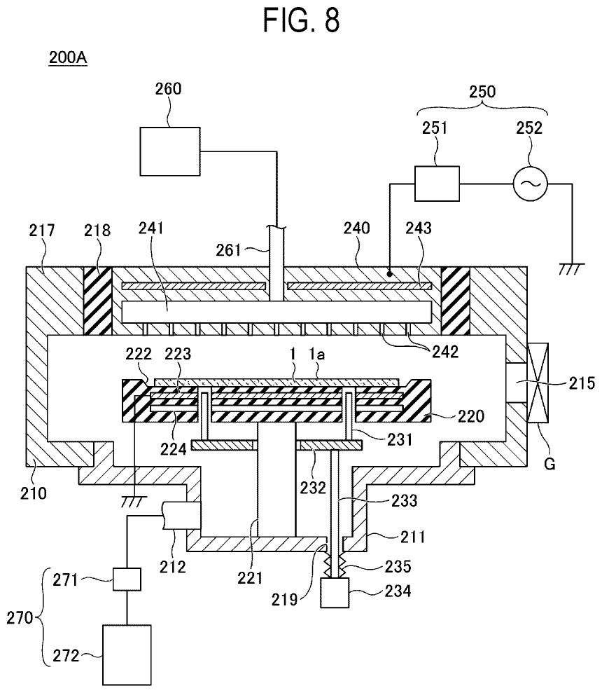

Next, the first processor 200A will be described with reference to FIG. 8. The second processor 200B, the third processor 200C, and the fourth processor 200D have the same configuration as that of the first processor 200A, and thus illustration and description thereof will be omitted.

The first processor 200A includes a substantially cylindrical airtight processing container 210. An exhaust chamber 211 is provided at a center portion of a bottom wall of the processing container 210. The exhaust chamber 211 has, for example, a substantially cylindrical shape that protrudes downward. An exhaust pipe 212 is connected to the exhaust chamber 211, for example, on the side of the exhaust chamber 211.

An exhaust source 272 is connected to the exhaust pipe 212 via a pressure controller 271. The pressure controller 271 includes, for example, a pressure regulating valve such as a butterfly valve. The exhaust pipe 212 is configured to depressurize the interior of the processing container 210 by the exhaust source 272. The pressure controller 271 and the exhaust source 272 constitute a gas discharge mechanism 270 that discharges gas from the interior of the processing container 210.

A transfer port 215 is provided in a side surface of the processing container 210. The transfer port 215 is open and closed by a gate valve G. The substrate 1 is loaded and unloaded between the interior of the processing container 210 and the second transfer chamber 411 (see FIG. 7) via the transfer port 215.

A stage 220, which is a holder for holding the substrate 1, is provided inside the processing container 210. The stage 220 holds the substrate 1 horizontally with the substrate surface 1a oriented upward. The stage 220 is formed in a substantially circular shape in a plan view and is supported by a support member 221. A recess 222 of a substantially circular shape is formed in a surface of the stage 220 to place the substrate 1 having a diameter of, for example, 300 mm. The recess 222 has an inner diameter slightly larger than the diameter of the substrate 1. A depth of the recess 222 is substantially the same as, for example, a thickness of the substrate 1. The stage 220 is made of, for example, a ceramic material such as aluminum nitride (AlN). The stage 220 may also be made of a metal material such as nickel (Ni). Instead of the recess 222, a guide ring that guides the substrate 1 may be provided at a peripheral edge of the surface of the stage 220.

In the stage 220, for example, a grounded lower electrode 223 is embedded. A heating mechanism 224 is embedded below the lower electrode 223. The heating mechanism 224 heats the substrate 1 placed on the stage 220 to a set temperature by being supplied with power from a power supply (not illustrated) based on a control signal from the controller 500 (see FIG. 7). When the entire stage 220 is made of a metal, the entire stage 220 functions as a lower electrode. Thus, the lower electrode 223 does not need to be embedded in the stage 220. The stage 220 is provided with a plurality (for example, three) of lifting pins 231 for holding and raising/lowering the substrate 1 placed on the stage 220. A material of the lifting pins 231 may be, for example, ceramic such as alumina (Al₂O₃), or quartz. Lower ends of the lifting pins 231 are attached to a support plate 232. The support plate 232 is connected to a lifting mechanism 234 provided outside the processing container 210 via a lifting shaft 233.

The lifting mechanism 234 is installed, for example, below the exhaust chamber 211. A bellows 235 is provided between an opening 219, which is formed in a bottom surface of the exhaust chamber 211 and used for the lifting shaft 233, and the lifting mechanism 234. The support plate 232 may be shaped to be raised and lowered without interfering with the support member 221 of the stage 220. The lifting pins 231 are configured to be movable up and down with respect to an upper surface of the stage 220 and a lower surface of the stage 220 by the lifting mechanism 234.

A gas supplier 240 is provided on a ceiling wall 217 of the processing container 210 via an insulating member 218. The gas supplier 240 constitutes an upper electrode and faces the lower electrode 223. A radio-frequency power supply 252 is connected to the gas supplier 240 via a matcher 251. By supplying radio-frequency power of 450 kHz to 100 MHz from the radio-frequency power supply 252 to the upper electrode (the gas supplier 240), a radio-frequency electric field is generated between the upper electrode (the gas supplier 240) and the lower electrode 223 to generate capacitively coupled plasma. A plasma generator 250 that generates plasma includes the matcher 251 and the radio-frequency power supply 252. Further, the plasma generator 250 may generate other plasma, such as inductively coupled plasma, without being limited to the capacitively coupled plasma. In Operations in which no plasma is generated (for example, Operations S103, and S105 to S107), the gas supplier 240 does not need to constitute the upper electrode, and thus the lower electrode 223 is also unnecessary.

The gas supplier 240 includes a hollow gas supply chamber 241. A plurality of holes 242 for distributively supplying a processing gas into the processing container 210 is arranged, for example, uniformly, in a lower surface of the gas supply chamber 241. In the gas supplier 240, a heating mechanism 243 is embedded, for example, above the gas supply chamber 241. The heating mechanism 243 is heated to a set temperature by being supplied with power from the power supply (not illustrated) based on the control signal from the controller 500.

A gas supply mechanism 260 is connected to the gas supply chamber 241 via a gas supply path 261. The gas supply mechanism 260 supplies gas to be used in at least one of Operations S102 to S108 in FIG. 1 to the gas supply chamber 241 via the gas supply path 261. Although not illustrated, the gas supply mechanism 260 includes an individual pipe, an on-off valve provided in the individual pipe, and a flow rate controller provided in the individual pipe, for each type of gas. When the individual pipe is open by the on-off valve, the gas is supplied from a supply source to the gas supply path 261. An amount of the gas supplied is controlled by the flow rate controller. On the other hand, when the individual pipe is closed by the on-off valve, the supply of the gas from the supply source to the gas supply path 261 is cutoff.

### Examples and Comparative Examples

Hereinafter, Examples 1 to 3 and Comparative Example 4 will be described.

In Example 1, a substrate having a low-k film and a Cu film in different regions of a substrate surface was prepared, and Operations S103 to S108 were performed while the substrate was heated to 150 degrees C. In Operation S103, a PFBA gas was supplied for 2 minutes. In Operation S104, a mixed gas of a H₂ gas and a N₂ gas was diluted with an Ar gas and supplied in a plasmarized state (power supply frequency: 40 MHz, power: 200 W, and processing pressure: 266 Pa) for 15 seconds. In Operation S105, an O₂ gas was supplied for 100 seconds (processing pressure: 665 Pa). In Operation S106, the supply of the PFOT gas and the supply of the O₂ gas were alternately repeated five times. In Operation S107A, supplying a TMA gas and supplying a H₂O gas were alternately repeated 10 times. In Operation S107B, the supply of the TMA gas (processing pressure: 665 Pa and processing time: 10 seconds) and supplying a TPSOL gas (processing pressure: 133 Pa and processing time: 30 seconds) were alternately repeated twice. In Operation S108, the supply of the H₂O gas (processing time: 10 seconds) and the supply of the plasmarized H₂ gas (processing time: 30 seconds) were alternately repeated six times. Thereafter, Operations S105 to S108 were performed only once again. In a second round of Operation S107, Operation S107B was performed without performing Operation S107A. In a second round of Operation S107B, the supply of the TMA gas (processing pressure: 665 Pa and processing time: 10 seconds) and the supply of the TPSOL gas (processing pressure: 133 Pa and processing time: 30 seconds) were alternately performed once. In this manner, a SiO film was selectively formed on the surface of the low-k film relative to the surface of the Cu film. The thickness of the SiO film was 6.2 nm. An amount of protrusion of the SiO film from the low-k film to the Cu film was 1.8 nm.

In Example 2, a substrate having a low-k film and a Cu film in different regions of a substrate surface was prepared. Operations S102 to S104 and S106 were performed while the substrate was heated to 150 degrees C. and then Operation S108 was performed while the substrate was heated to 85 degrees C. In Operation S102, a mixed gas of the H₂ gas and the N₂ gas was diluted with the Ar gas and supplied in a plasmarized state (power supply frequency: 40 MHz, power: 200 W, and processing pressure: 266 Pa) for 15 seconds, and then the O₂ gas was supplied for 30 seconds (processing pressure: 665 Pa). In Operation S103, the PFBA gas was supplied for two minutes. In Operation S104, the H₂ gas was diluted with the Ar gas and supplied in a plasmarized state (power supply frequency: 40 MHz, power: 200 W, and processing pressure: 266 Pa) for 30 seconds. In Operation S106, the PFHT (CF₃(CF₂)₃CH₂CH₂SH) gas was supplied for five minutes. In Operation S107A, the supply of the TMA gas and the supply of the H₂O gas were alternately repeated 10 times. In Operation S107B, the supply of the TMA gas (processing pressure: 665 Pa and processing time: 10 seconds) and the supply of the TPSOL gas (processing pressure: 133 Pa and processing time: 15 seconds) were alternately repeated once. In Operation S108, the supply of the H₂O gas (processing time: 10 seconds) and the supply of the plasmarized H₂ gas (processing time: 30 seconds) were alternately repeated five times. Thereafter, Operations S105 to S108 were performed only once again. In the second round of Operation S107, Operation S107B was performed without performing Operation S107A. In the second round of Operation S107B, the supply of the TMA gas (processing pressure: 665 Pa and processing time: 10 seconds) and the supply of the TPSOL gas (processing pressure: 133 Pa and processing time: 15 seconds) were alternately performed once. In this manner, the SiO film was selectively formed on the surface of the low-k film relative to the surface of the Cu film. The thickness of the SiO film was 5.7 nm. The amount of protrusion of the SiO film from the low-k film to the Cu film was 2.3 nm.

In Example 3, a substrate having a low-k film and a cap film (specifically, a Co film covering a Cu film) in different regions of a substrate surface was prepared. Operations S102 to S104, S106, and S107 were performed while the substrate was heated to 150 degrees C. and then Operation S108 was performed while the substrate was heated to 85 degrees C. In Operation S102, a mixed gas of the H₂ gas and the N₂ gas was diluted with the Ar gas and supplied in a plasmarized state (power supply frequency: 40 MHz, power: 200 W, and processing pressure: 266 Pa) for 15 seconds, and then the O₂ gas was supplied for 30 seconds (processing pressure: 665 Pa). In Operation S103, the PFNO gas was supplied for two minutes. In Operation S104, the mixed gas of the H₂ gas and the N₂ gas was diluted with the Ar gas and supplied in a plasmarized state (power supply frequency: 40 MHz, power: 200 W, and processing pressure: 266 Pa) for 15 seconds. In Operation S106, the PFNO gas was supplied for five minutes. In Operation S107A, the supply of the TMA gas and the supply of the H₂O gas were alternately repeated 10 times. In Operation S107B, the supply of the TMA gas (processing pressure: 665 Pa and processing time: 10 seconds) and the supply of the TPSOL gas (processing pressure: 133 Pa and processing time: 7.5 seconds) were alternately repeated once. In Operation S108, the supply of the H₂O gas (processing time: 10 seconds) and the supply of the plasmarized H₂ gas (processing time: 30 seconds) were alternately repeated three times. Thereafter, Operations S105 to S108 were performed only once again. In the second round of Operation S107, Operation S107B was performed without performing Operation S107A. In the second round of Operation S107B, the supply of the TMA gas (processing pressure: 665 Pa and processing time: 10 seconds) and the supply of the TPSOL gas (processing pressure: 133 Pa and processing time: 7.5 seconds) were alternately performed once. In this manner, a SiO film was selectively formed on the surface of the low-k film relative to the surface of the cap film. The thickness of the SiO film was 5.2 nm. The amount of protrusion of the SiO film from the low-k film to the cap film was 1.2 nm.

In Comparative Example 4, a substrate having a low-k film and a Cu film in different regions of a substrate surface was prepared in the same manner as in Example 1, except that Operation S103 was not performed, and Operations S104 to S108 were performed while the substrate was heated to 150 degrees C. In Comparative Example 4, unlike Example 1, in Operation S107B, the supply of the TMA gas (processing pressure: 665 Pa and processing time: 10 seconds) and the supply of the TPSOL gas (processing pressure: 133 Pa and processing time: 30 seconds) were alternately repeated four times. In Comparative Example 4, unlike Example 1, Operations S105 to S108 were not performed again. In this way, a SiO film was selectively formed on the surface of the low-k film relative to the surface of the Cu film. The thickness of the SiO film was 3.6 nm. The amount of protrusion of the SiO film from the low-k film onto the Cu film was 2.7 nm.

The number of execution times of a cycle including the supply of the TMA gas and the supply of the TPSOL gas was three times (two times plus one time) in total in Example 1, whereas the number of execution times of the cycle was four in Comparative Example 4. Nevertheless, the thickness of the SiO film finally obtained was 6.2 nm in Example 1, whereas the thickness of the SiO film was 3.6 nm in Comparative Example 4. This shows that the SiO film may be efficiently formed on the surface of the low-k film by performing Operation S103.

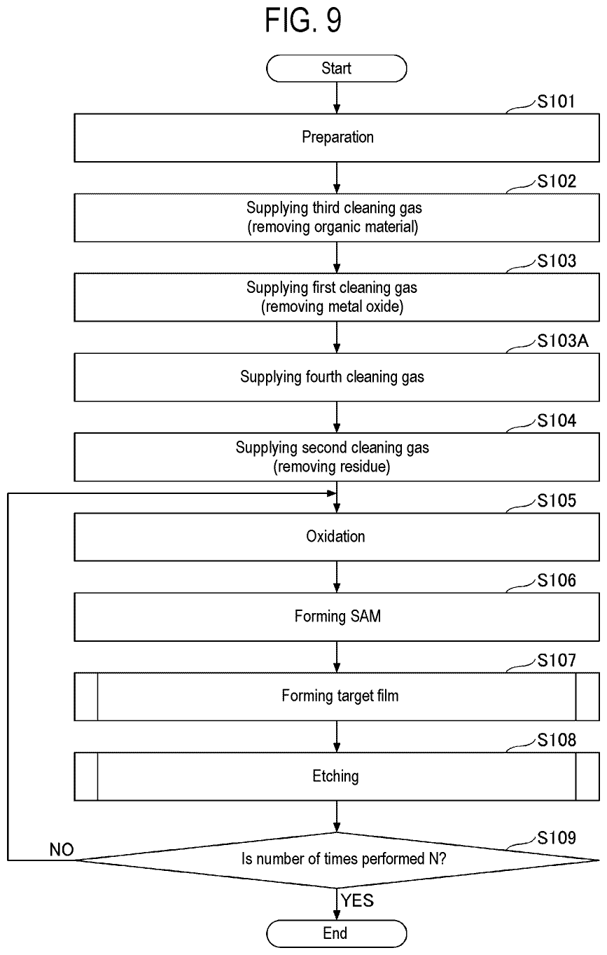

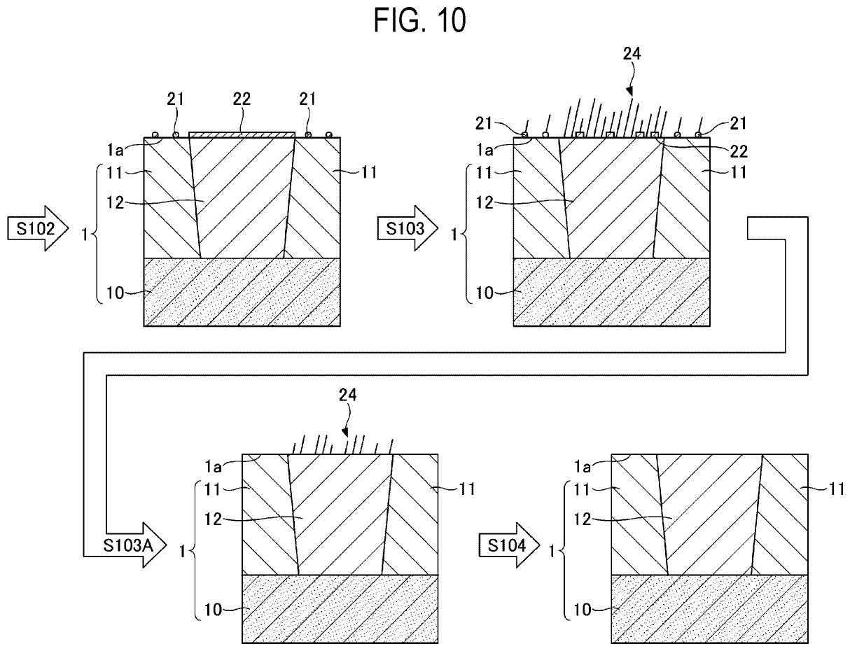

Next, a modification of FIG. 1 will be described with reference to FIGS. 9 and 10. As illustrated in FIG. 9, the film formation method may include Operation S103A after Operation S103 and before Operation S104. In Operation S103A, a fourth cleaning gas that is not plasmarized is supplied to the substrate surface 1a. The fourth cleaning gas includes a reducing gas or an inert gas. The reducing gas includes, for example, a hydrogen gas. The inert gas includes, for example, a nitrogen gas or a noble gas. The fourth cleaning gas does not include an oxidizing gas such as an oxygen gas.

As illustrated in FIG. 10, the fourth cleaning gas that is not plasmarized removes the contaminants 21 and 22 that could not be completely removed in Operation S103. The contaminants 21 and 22 have been modified into volatile substances by reaction with the first cleaning gas in Operation S103 and thus may be removed in Operation S103A. The reason why the fourth cleaning gas is not plasmarized in Operation S103A is to suppress deterioration of the substrate surface 1a due to plasma. For the same reason, it is desirable not to plasmarize the first cleaning gas even in Operation S103.

An example of a case in which the contaminants 21 and 22 cannot be completely removed in Operation S103 may include a case in which the first cleaning gas does not contain fluorine from the viewpoint of environmental load. A reaction product that does not contain fluorine has lower volatility than a reaction product that contains fluorine. Therefore, in the case in which the first cleaning gas does not contain fluorine, there are cases in which the contaminants 21 and 22 cannot be completely removed in Operation S103. An example of carboxylic acid that does not contain fluorine may include acetic acid (CH₃COOH).

In the case in which the first cleaning gas does not contain fluorine, it is desirable to perform Operation S103A. Even if the first cleaning gas contains fluorine, in the case in which the first cleaning gas does not contain a trifluoromethyl (CF₃) group, the reaction product generated by the reaction between the contaminants 21 and 22 and the first cleaning gas has a relatively low volatility. Therefore, Operation S103A may be performed when the first cleaning gas does not contain the trifluoromethyl (CF₃) group. However, Operation S103A may be performed even if the first cleaning gas contains the trifluoromethyl (CF₃) group.

Operation S103A is performed before Operation S104. When Operation S103A is performed after Operation S104, a volatile substance, which is the reaction product obtained by the reaction between the contaminants 21 and 22 and the first cleaning gas, is further modified in Operation S104, which makes it difficult to remove the contaminants 21 and 22 in Operation S103A. According to the present modification, since Operation S103A is performed before Operation S104, the contaminants 21 and 22 may be removed in Operation S103A.

An example of processing conditions used in Operation S103A is as follows.
Flow rate of H₂ gas: 50 sccm to 5,000 sccm
Flow rate of Ar gas: 20 sccm to 10,000 sccm
Ratio of H₂ gas in fourth cleaning gas: 10 vol % to 60 vol %
Processing time: 5 seconds to 600 seconds
Processing temperature (substrate temperature): 80 degrees C. to 350 degrees C.
Processing pressure: 50 Pa to 300 Pa.

According to the present disclosure in some embodiments, it is possible to selectively form a SAM in a desired region.

While the embodiments of a film formation method and a film formation apparatus according to the present disclosure have been described, these embodiments have been presented by way of example only, and are not intended to limit the scope of the disclosures. Indeed, the embodiments described herein may be embodied in a variety of other forms. Further, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film formation method comprising:
preparing a substrate having a first film and a second film made of a material different from a material of the first film in different regions of a surface of the substrate;
supplying, to the surface of the substrate, a first cleaning gas that removes a contaminant on the surface of the substrate;
supplying, to the surface of the substrate, a second cleaning gas plasmarized to remove a residue of the first cleaning gas adhering to the surface of the substrate; and
after supplying the second cleaning gas, selectively forming a self-assembled monolayer on a surface of the second film relative to a surface of the first film,
wherein the first cleaning gas includes at least one selected from a group consisting of a carboxylic acid compound, a phosphonic acid compound, a nitro compound, and a thiol compound.

2. The film formation method of claim 1, wherein the first cleaning gas and a raw material gas of the self-assembled monolayer include a same organic compound.

3. The film formation method of claim 1, wherein the first cleaning gas removes a metal or a metal oxide, which is the contaminant on the surface of the substrate, and
wherein the film formation method comprises supplying, to the surface of the substrate, a third cleaning gas that removes an organic material, which is the contaminant on the surface of the substrate, before supplying the first cleaning gas.

4. The film formation method of claim 1, wherein the second cleaning gas includes a reducing gas.

5. The film formation method of claim 4, wherein a raw material gas of the self-assembled monolayer includes a nitro compound, and
wherein the second cleaning gas includes the reducing gas and a nitrogen-containing gas.

6. The film formation method of claim 1, wherein the first film is an insulating film and the second film is a conductive film.

7. The film formation method of claim 6, wherein the conductive film is a Cu film, a Co film, a Ru film, a W film, or a Mo film.

8. The film formation method of claim 1, further comprising: forming a target film on a surface of the first film while inhibiting the target film from being formed on a surface of the second film using the self-assembled monolayer.

9. The film formation method of claim 1, wherein the first cleaning gas does not contain fluorine,
wherein the film formation method comprises supplying a fourth cleaning gas, which is not plasmarized, to the surface of the substrate after supplying the first cleaning gas and before supplying the second cleaning gas, and
wherein the fourth cleaning gas includes a reducing gas or an inert gas.

10. A film formation apparatus comprising:
a processing container;
a holder provided in an interior of the processing container to hold the substrate;
a gas supply mechanism configured to supply a gas to the interior of the processing container;
a gas discharge mechanism configured to discharge the gas from the interior of the processing container;
a transfer mechanism configured to load or unload the substrate into or from the processing container; and
a controller configured to control the gas supply mechanism, the gas discharge mechanism, and the transfer mechanism so as to execute the film formation method of claim 1.
